(19) United States
(12) Patent Application Publication
(10) Pub. No.: US 2025/0273946 A1
(43) Pub. Date: Aug. 28, 2025

(54) CONTACTOR CONTROL CIRCUIT AND BATTERY PACK INCLUDING THE SAME

(71) Applicant: Samsung SDI Co., Ltd., Yongin-si (KR)

(72) Inventor: Kiseon KIM, Yongin-si (KR)

(73) Assignee: Samsung SDI Co., Ltd., Yongin-si (KR)

(21) Appl. No.: 18/975,893

(22) Filed: Dec. 10, 2024

(30) Foreign Application Priority Data
Feb. 26, 2024 (KR) 10-2024-0027515

(51) Int. Cl. H02H 3/027; H01M 10/42; H01M 50/502; H02H 1/04

(52) U.S. Cl. CPC H02H 3/027; H01M 10/4264; H01M 50/502; H02H 1/04; H01M 2010/4271

(57) ABSTRACT

A contactor control circuit includes a first input terminal receiving a driving signal, a second input terminal receiving a false signal, a resistor and a capacitor connected in parallel to each other between an intermediate node and a ground, a transistor switch configured to transmit the driving signal to the intermediate node when the false signal is at a low level, a logic OR circuit configured to generate a control signal by performing an OR operation on logic levels of the driving signal and the intermediate node, and an output terminal outputting the control signal.

### CROSS-REFERENCE TO RELATED APPLICATIONS

This present application claims priority to and the benefit under 35 U.S.C. § 119(a)-(d) of Korean Patent Application No. 10-2024-0027515, filed on Feb. 26, 2024, in the Korean Intellectual Property Office, the entire disclosure of which is incorporated herein by reference.

### FIELD

One or more embodiments relate to a contactor control circuit of a battery pack, and more particularly, to a contactor control circuit having a retention function.

### BACKGROUND

A secondary battery can be charged and discharged, unlike a primary battery that cannot be recharged. Small batteries are used for small portable electronic devices such as smart phones, feature phones, laptop computers, digital cameras, and camcorders, and large batteries are widely used for hybrid vehicles, electric vehicles, and energy storage systems.

A battery cell, which is a basic unit of a secondary battery, includes an electrode assembly, which electrode assembly includes an anode, a separator, a cathode, an electrode terminal connected to each of the anode and the cathode, and a case accommodating the electrode assembly and an electrolyte, as well as other elements. A battery module is an assembly that is a frame into which a certain number of battery cells are coupled to increase output of a battery and protect the battery against external shock, heat, and vibration. A battery pack is completed by connecting several battery modules and adding a battery management system for thermal management and electrical control. The battery management system includes a micro control unit (MCU), a sensor, an analog front end (AFE), a protection device, and other electronic circuits. The battery management system further includes a power management integrated circuit (IC, PMIC) that supplies driving power to the MCU and the AFE, checks the operation of the MCU, and outputs a false signal when a false state of the MCU is detected.

However, in an external environment, an electrical or physical shock such as a thunderstorm may cause a temporary communication failure between the MCU and the PMIC, causing a false signal to be output. As this does not mean that a fault has actually occurred in the MCU, a retention function is provided that allows a contactor to maintain its previous state for a certain period of time so as not to perform a protection function immediately in response to a false signal. In the art, control circuits such as timer ICs and D-flip flops have been used to implement a retention function, but the addition of these control circuits increase manufacturing costs and require the supply of a separate driving power source for the control circuits.

The above-described information disclosed in the technology section that serves as the background of the present disclosure is only for improving the understanding of the background of the present disclosure, and thus may include information that does not constitute prior art.

### SUMMARY

One or more embodiments include a contactor control circuit having a retention function and a battery pack including the contactor control circuit.

Additional aspects will be set forth in part in the description which follows and, at least in part, will be apparent from the description, or may be learned by practice of the presented embodiments of the present disclosure.

According to one or more embodiments, a contactor control circuit includes a first input terminal receiving a driving signal, a second input terminal receiving a false signal, a resistor and a capacitor connected in parallel to each other between an intermediate node and a ground, a transistor switch configured to transmit the driving signal to the intermediate node when the false signal is at a low level, a logic OR circuit configured to generate a control signal by performing an OR operation on logic levels of the driving signal and the intermediate node, and an output terminal outputting the control signal.

In an example, the transistor switch may include a pnp transistor including a base connected to the second input terminal, an emitter connected to the first input terminal, and a collector connected to the intermediate node.

In another example, the OR circuit may include a first OR gate configured to generate a logic signal by performing the OR operation on a voltage level of the intermediate node and a voltage of the ground and a second OR gate configured to generate the control signal by performing the OR operation on the driving signal and the logic signal.

In another example, charge corresponding to a voltage level of the driving signal at a moment at which the transistor switch is turned off as the false signal transitions to a high level may be charged in the capacitor.

In another example, if charge corresponding to a first voltage level of the driving signal at a moment at which the transistor switch is turned off is charged in the capacitor, a voltage level of the intermediate node may be maintained higher than a reference voltage level of the OR circuit for a preset retention time even if the charge charged in the capacitor is discharged through the resistor according to a time constant determined by a resistance of the resistor and a capacitance of the capacitor.

According to one or more embodiments, a battery pack includes a first pack terminal and a second pack terminal, a battery including at least one battery cell, a contactor connected between the battery and the first pack terminal, a micro control unit (MCU) configured to output a driving signal, a power management integrated circuit (PMIC) configured to monitor a state of the MCU and output a false signal, and a contactor control circuit configured to receive the driving signal through a first input terminal, receive the false signal through a second input terminal, generate, based on the driving signal and the false signal, a control signal for controlling the contactor, and output the control signal through an output terminal. The contactor control circuit may include a resistor and a capacitor connected in parallel to each other between an intermediate node and a ground, a transistor switch configured to transmit the driving signal to the intermediate node when the false signal is at a low level, and a logic OR circuit configured to generate a control signal by performing an OR operation on logic levels of the driving signal and the intermediate node.

In an example, the MCU may be further configured to output the driving signal of a first voltage level to short-circuit the contactor and output the driving signal of the low level to separate the contactor. The PMIC may be further configured to output the false signal of the first voltage level when the MCU is in a normal state, and output the false signal of the low level when the MCU is monitored as being in a false state.

In another example, the transistor switch may include a pnp transistor including a base connected to the second input terminal, an emitter connected to the first input terminal, and a collector connected to the intermediate node.

In another example, the OR circuit may include a first OR gate configured to generate a logic signal by performing the OR operation on a voltage level of the intermediate node and a voltage of the ground and a second OR gate configured to generate the control signal by performing the OR operation on the driving signal and the logic signal.

In another example, charge corresponding to a voltage level of the driving signal at a moment at which the transistor switch is turned off as the false signal transitions to a high level may be charged in the capacitor.

In another example, if charge corresponding to a first voltage level of the driving signal at a moment at which the transistor switch is turned off is charged in the capacitor, a voltage level of the intermediate node may be maintained higher than a reference voltage level of the OR circuit for a preset retention time even if the charge charged in the capacitor is discharged through the resistor according to a time constant determined by a resistance of the resistor and a capacitance of the capacitor.

An embodiment is directed to a method of making a contactor control circuit comprising steps of: providing a first input terminal adapted to receive a driving signal; providing a second input terminal adapted to receive a false signal; connecting in parallel to each other between an intermediate node and a ground a resistor and a capacitor; providing a transistor switch configured to transmit to the intermediate node when the false signal is at a low level the driving signal; providing a logic OR circuit configured to generate a control signal by performing on logic levels of the driving signal and the intermediate node an OR operation; and providing an output terminal configured to output the control signal.

### BRIEF DESCRIPTION OF THE DRAWINGS

The above and other aspects, features, and advantages of certain embodiments of the present disclosure will be more apparent from the following description taken in conjunction with the accompanying drawings.

By describing embodiments in more detail below with reference to the accompanying drawings, features will become clear to those of ordinary skill in the art.

FIG. 1 schematically shows a battery pack according to embodiments of the present disclosure;

FIG. 2 is a circuit diagram of a contactor control circuit according to embodiments of the present disclosure;

FIG. 3 is a circuit diagram of a contactor control circuit according to other embodiments of the present disclosure;

FIG. 4 is a signal waveform diagram of the contactor control circuit of FIG. 3; and

FIG. 5 is a signal waveform diagram of the contactor control circuit of FIG. 3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Now, embodiments will be described in more detail with reference to the drawings attached below. However, the present disclosure may be embodied in many forms and should not be considered as being limited to the embodiments described herein. Rather, these embodiments are provided to complete the present disclosure and convey specific embodiments to those of ordinary skill in the art.

The terms used herein are used to describe particular embodiments, and is not intended to limit the present disclosure. Singular forms may include plural forms unless apparently indicated otherwise contextually. Moreover, it should be understood that the term “include”, “have”, or the like used herein is to indicate the presence of features, numbers, steps, operations, elements, parts, or a combination thereof described in the specification, and does not preclude the presence or addition of one or more other features, numbers, steps, operations, elements, parts, or a combination thereof. The terms, first, second, etc., may be used to describe various components, but the components are not limited by these terms. These terms are used to distinguish one component from another component.

Embodiments will now be more completely described with reference to the accompanying drawings in which embodiments are shown. Identical reference numerals refer to identical components throughout. In the drawings, identical or corresponding components are given the same reference numerals and will not be described repeatedly.

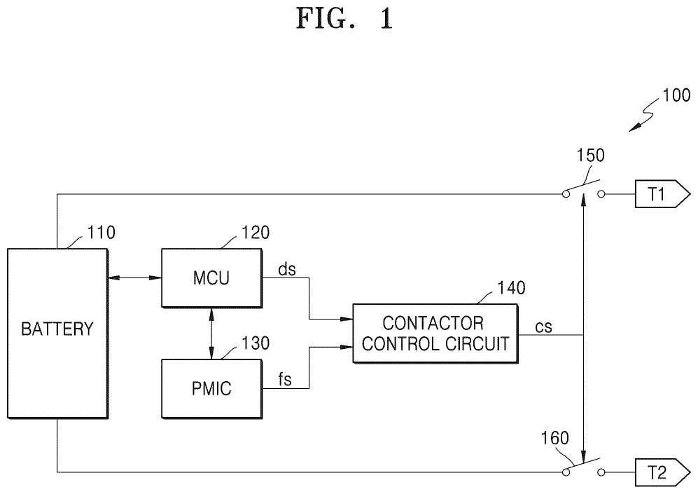

FIG. 1 schematically shows a battery pack according to embodiments of the present disclosure.

Referring to FIG. 1, a battery pack 100 may include a battery 110 connected between a first pack terminal T1 and a second pack terminal T2, a micro control unit (MCU) 120, a power management integrated circuit (IC, PMIC) 130, a contactor control circuit 140, a first contactor 150, and a second contactor 160.

The battery 110 may include at least one battery cell. The battery 110 may include a plurality of battery modules electrically connected to each other. Each battery module may include a plurality of battery cells.

A battery cell may be a chargeable secondary battery for storing power. For example, the battery cell may include at least one selected from a group including a lithium-ion battery, a lithium polymer battery, a nickel cadmium battery, a nickel metal hybrid (Ni-MH) battery, a nickel-zinc (Ni—Zn) battery, a lead-acid battery, etc.

The total number and connection configuration of battery cells included in the battery 110 may be determined according to an output voltage and a power storage capacity required for the battery pack 100.

The battery 110 may be connected to the first pack terminal T1 through the first contactor 150 and to the second pack terminal T2 through the second contactor 160. The first contactor 150 and the second contactor 160 may be, for example, relay contactors. The first contactor 150 and the second contactor 160 may be commonly short-circuited (i.e., turned on) or open (i.e., turned off) based on a control signal cs output from the contactor control circuit 140. FIG. 1 shows the first contactor 150 and the second contactor 160, respectively, connected to the anode and the cathode of the battery 110, but one of the first contactor 150 and the second contactor 160 may be omitted.

The battery pack 100 may include a battery management system for managing the battery pack 100. The battery management system may include an MCU 120 that performs overall management and protection operations, a PMIC 130 that supplies driving power required for the MCU 120 and monitors a state of the MCU 120, and a contactor control circuit 140 for controlling the first and second contactors 150 and 160. The battery management system may further include the AFE, sensing devices such as a current sensor and a temperature sensor, and a contactor driving circuit for directly controlling the first and second contactors 150 and 160 in addition to the MCU 120, the PMIC 130, and the contactor control circuit 140.

The AFE may monitor cell voltages of battery cells included in the battery 110. The AFE may monitor a temperature of the battery 110 by using the temperature sensor. The AFE may monitor charging current and discharging current of the battery 110 by using the current sensor. The battery management system may include a cell balancing circuit for equalizing the cell voltages of the battery cells included in the battery 110. The AFE may control the cell balancing circuit. The AFE MAY provide to the MCU 120 monitored data and under the control of the MCU 120 perform operations.

The MCU 120 may collect state information of the battery 110 provided from the AFE, manage the overall operation of the battery pack 100 based on the state information, and perform operations for protecting the battery 110. For example, the MCU 120 may determine whether a false state such as over-charge, over-discharge, high temperature, over-current, etc., occurs by comparing battery data with a preset reference value. If the MCU 120 determines that the battery 110 is in a normal state, the MCU 120 may output a driving signal ds of a first voltage level to charge or discharge the battery 110. If the MCU 120 determines that the false state has occurred, the MCU 120 may output to separate the battery 110a driving signal ds at a second voltage level. The first voltage level may be a high level, and the second voltage level may be a low level. For example, the first voltage level may be +5 V, and the second voltage level may be 0 V or a ground voltage.

The PMIC 130 may provide driving power for driving circuits such as the MCU 120 and electrical devices in the battery management system. The PMIC 130 may monitor a state of the MCU 120. For example, if the PMIC 130 determines that the MCU 120 is in the false state, the PMIC 130 may temporarily block the driving voltage supplied to the MCU 120 or provide a reset voltage to reset or reboot the MCU 120. To this end, the PMIC 130 may communicate with the MCU 120 at a preset cycle or exchange pulses. For example, if communication with the MCU 120 is lost or pulses are not received for a preset time, the PMIC 130 may determine that a fault has occurred in the MCU 120. The PMIC 130 may output a false signal fs indicating the state of the MCU 120. For example, the PMIC 130 may output the false signal fs of the first voltage level if determining that the MCU is in the normal state, and may output the false signal fs of the second voltage level if determining that the MCU 120 is in the false state. For example, the first voltage level may be +5 V, and the second voltage level may be 0 V or a ground voltage. The state of the PMIC 130 may be monitored by the MCU 120.

The contactor control circuit 140 may receive from the MCU 120 the driving signal ds, receive from the PMIC 130 the false signal fs, and generate the control signal cs for controlling the first and second contactors 150 and 160 based on the driving signal ds and the false signal fs. The contactor control signal 14 may include a first input terminal for receiving the driving signal ds, a second input terminal for receiving the false signal fs, and an output terminal for outputting the control signal cs. For example, if the driving signal ds is at a high level, the contactor control circuit 140 may output the control signal cs of a high level. If the low-level false signal fs is temporarily received in the contactor control circuit 140, the contactor control circuit 140 may output the control signal cs in the previous state for a preset retention time even if the low-level driving signal ds is received. In this sense, the contactor control circuit 140 may be referred to as a retention circuit having a retention function. If the low-level driving signal ds is received in a state in which the low-level false signal fs is received in the contactor control circuit 140, the contactor control circuit 140 may output the low-level control signal cs in response to the low-level driving signal ds in spite of the retention function.

The first and second contactors 150 and 160 may be short-circuited based on the high-level control signal cs and open based on the low-level control signal cs. The high-level control signal cs may be, for example, 1 V, and the low-level control signal cs may be, for example, 0 V or the ground voltage.

Although not shown in FIG. 1, the battery pack 100 may further include a contactor driving circuit that outputs a contactor driving voltage in response to the high-level control signal cs. The contactor driving circuit may include a driving switch which is connected between an input terminal to which a contactor driving voltage is applied and control terminals of the first and second contactors 150 and 160 and controlled by the control signal cs. The driving switch may be, for example, a metal-oxide-semiconductor field effect transistor (MOSFET), and may be turned on in response to the high-level control signal cs and turned off in response to the low-level control signal cs.

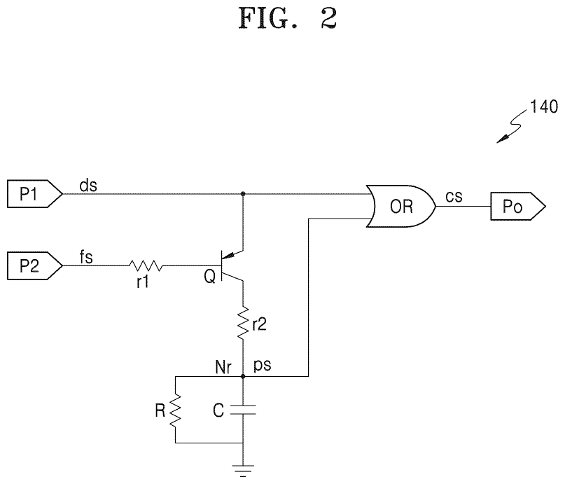

The contactor control circuit 140 will be described in more detail with reference to FIGS. 2 to 5.

FIG. 2 is a circuit diagram of a contactor control circuit according to embodiments of the present disclosure.

Referring to FIG. 2, the contactor control circuit 140 may include a first input terminal P1 for receiving from the MCU 120 the driving signal ds, a second input terminal P2 for receiving from the PMIC 130 the false signal fs, and an output terminal Po for outputting the control signal cs. The contactor control circuit 140 may include a resistor R and a capacitor C connected in parallel between an intermediate node Nr and the ground, a transistor switch Q for transmitting the driving signal ds to the intermediate node Nr when the false signal fs is at the low level, and a logic OR circuit for generating the control signal cs by performing an OR operation on the driving signal ds and the intermediate node Nr.

The transistor switch Q may be a transistor that is turned on in response to the low-level control signal cs. For example, the transistor switch Q may be a pnp transistor as shown in FIG. 2, in which a base may be connected to the second input terminal P2 through a first resistor r1, an emitter may be connected to the first input terminal P1, and a collector may be connected to the intermediate node Nr through a second resistor r2.

In another example, the transistor switch Q may be a p-type MOSFET and may have a source connected to the first input terminal P1, a gate connected to the second input terminal P2, and a drain connected to the intermediate node Nr.

The resistor R and the capacitor C may form a resistor-capacitor circuit RC between the intermediate node Nr and the ground, and if the transistor switch Q is turned off, the voltage level of the intermediate node Nr may decrease a time constant determined by a resistance of the resistor R and a capacitance of the capacitor C. That is, the charge stored in the capacitor C may be discharged through the resistor R at a rate according to the time constant. If the transistor switch Q is turned on, the voltage level of the intermediate node Nr may change according to a time constant determined by a resistance of the second resistor r2, the resistance of the resistor R, and the capacitance of the capacitor C. The resistance of the second resistor r2 may be designed to be negligibly less than the resistance of the resistor R such that the voltage level of the intermediate node Nr may rapidly change when the transistor switch Q is turned on, and may slowly change when the transistor switch Q is turned off.

When the MCU 120 operates normally, the PMIC 130 may output the high-level false signal fs and the transistor switch Q may be turned off. The charge stored in the capacitor C may be discharged through the resistor R, and the voltage level of the intermediate node Nr may equal that of the ground. In this case, the intermediate node Nr may output a low-level voltage signal ps.

If the PMIC 130 detects the false state of the MCU 120 and outputs the low-level false signal fs, the transistor switch Q may be turned on in response to the low-level false signal fs. The driving signal ds may be transmitted to the intermediate node Nr through the turned-on transistor switch Q. The voltage level of the intermediate node Nr may correspond to the voltage level of the driving signal ds input through the first input terminal P1. The intermediate node Nr may output the voltage signal ps of the same voltage level as the driving signal ds.

The false signal fs may transition to the high level. For example, if a temporary communication fault occurs between the PMIC 130 and the MCU, the PMIC 130 may output the high-level false signal fs upon detecting that communication with the MCU 120 is recovered normally. The transistor switch Q may be turned off in response to the false signal fs transitioning to the high level, and the charge corresponding to the voltage level of the driving signal ds at that time may be stored in the capacitor C.

If the driving signal ds at the moment when the transistor switch Q is turned off is at the first voltage level, the intermediate node Nr may output the voltage signal ps of the first voltage level, and the charge corresponding to the first voltage level may be charged in the capacitor C. The charge charged in the capacitor C may be discharged through the resistor R according to a time constant determined by the resistance of the resistor R and the capacitance of the capacitor C.

The voltage level of the intermediate node Nr exponentially decreases from the first voltage level, but may be maintained higher than a reference voltage level of the OR circuit for a preset retention time. The reference voltage level of the OR circuit may be a criterion for determining a voltage level of an input signal as high or low. For example, the reference voltage level may be 0.5 V. That is, the OR circuit may determine a voltage signal higher than 0.5 V as high and a voltage signal lower than 0.5 V as low.

The preset retention time may be, for example, 3 seconds. In this case, at the moment when the transistor switch Q is turned off, the voltage level of the intermediate node Nr may be the first voltage level, the voltage level of the intermediate node Nr may decrease exponentially, and the intermediate node Nr may decrease to the reference voltage level after the elapse of the preset retention time.

The OR circuit may receive the driving signal ds and the voltage signal ps of the intermediate node Nr and perform the OR operation on the driving signal ds and the voltage signal ps to generate the control signal cs. The OR circuit may output the control signal cs to the output terminal Po. The OR circuit may be an OR gate.

For example, if the driving signal ds is at the high level, the OR circuit may output the high-level control signal cs. When the driving signal ds is at the low level, the OR circuit may output the control signal cs of the same logic level as the voltage signal ps of the intermediate node Nr. If the low-level false signal fs is temporarily input to the second input terminal P2 when the driving signal ds is at the high level, the intermediate node Nr may output the high-level voltage signal ps for a preset retention time even if the driving signal ds transitions to the low level, and the OR circuit may output the high-level control signal cs for the retention time.

Thus, the first contactor 150 and the second contactor 160 controlled based on the control signal cs may maintain a short-circuited state for the retention time. For a reason such as a temporary communication failure, the first contactor 150 and the second contactor 160 may be separated from each other, thereby preventing a failure, such as interruption of power supply to an electrical load, or the like, from being amplified.

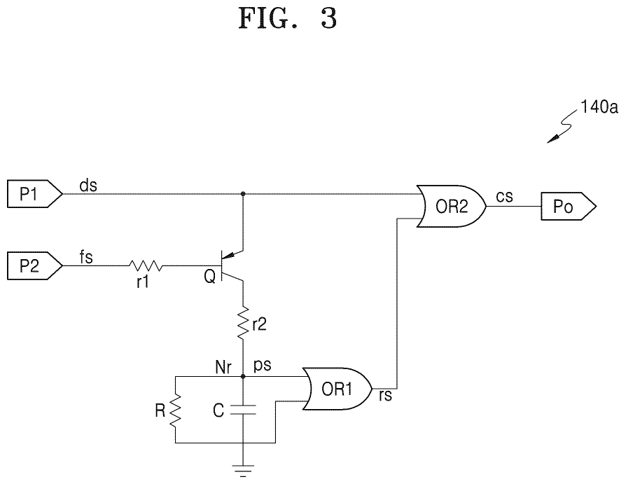

FIG. 3 is a circuit diagram of a contactor control circuit according to other embodiments of the present disclosure.

Referring to FIG. 3, a contactor control circuit 140a may be substantially the same as the contactor control circuit 140 of FIG. 2 except for the OR circuit of the contactor control circuit 140. The contactor control circuit 140a may include a first OR gate OR1 and a second OR gate OR2 to generate the control signal cs by performing the OR operation on the logic levels of the driving signal ds and the intermediate node Nr.

The first OR gate OR1 may generate a logic signal rs by performing the OR operation on the voltage signal ps of the intermediate node Nr and the ground voltage. The first OR gate OR1 may output the logic signal rs having the same logic level as the voltage signal ps by deciding the logic level of the voltage signal ps. The first OR gate OR1 may be replaced with a buffer gate that receives the voltage signal ps of the intermediate node Nr and outputs the logic signal rs.

For example, the high-level logic signal rs may be output when the voltage level of the intermediate node Nr is higher than the reference voltage level, and the low-level logic signal rs may be output when the voltage level of the intermediate node Nr is lower than the reference voltage level.

The second OR gate OR2 may generate the control signal cs by performing the OR operation on the driving signal ds and the logic signal rs. If the driving signal ds is at the high level, the high-level control signal cs may be output. If the driving signal ds is at the low level, the control signal cs having the same logic level as the logic signal rs may be output.

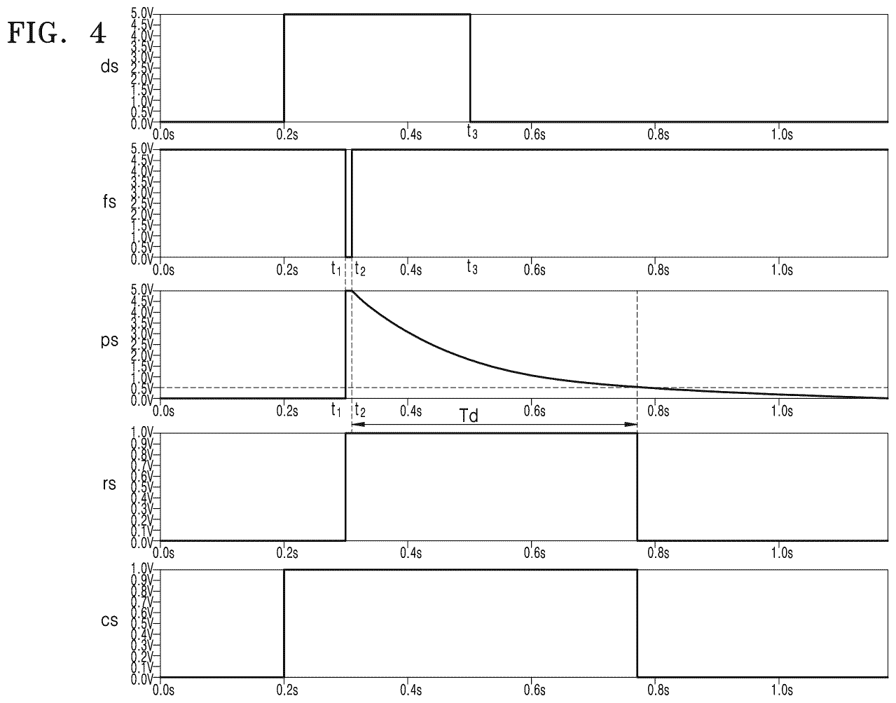

FIG. 4 is a signal waveform diagram of the contactor control circuit of FIG. 3.

Referring to FIG. 4, the low-level false signal fs temporarily occurs for a reason, such as a temporary communication failure.

At 0.0 s, the driving signal ds is at the low level and the false signal fs is at the high level. The voltage level of the false signal fs may be, for example, 5 V. The transistor switch Q may be turned off by the high-level false signal fs, and the charge stored in the capacitor C may be discharged through the resistor R and thus the voltage signal ps of the intermediate node Nr may be at the low level. The logic signal rs output by the first OR gate OR1 may also be at the low level, and the second OR gate OR2 may output the low-level control signal cs according to the low-level driving signal ds and the low-level logic signal rs.

At 0.2 s, the driving signal ds may transition to the high level. The voltage level of the driving signal ds may be, for example, 5 V. For example, the MCU (120 of FIG. 1) may output the high-level driving signal ds to supply power of the battery 110 to the electrical load connected to the battery pack 100 or to receive power from a charging device. The second OR gate OR2 may output the high-level control signal cs according to the high-level driving signal ds. The first contactor 150 and the second contactor 160 may be short-circuited according to the high-level control signal cs, and the battery 110 may supply power to the electrical load connected to the first pack terminal T1 and the second pack terminal T2 or receive power from a charging device.

The false signal fs may be still at the high level, such that the transistor switch Q may maintain a turn-off state and the voltage signal ps and the logic signal rs may maintain the low level.

At t₁, the PMIC (130 of FIG. 1) may detect the false state of the MCU 120 and output the low-level false signal fs. If the false signal fs transitions to the low level, the transistor switch Q may be turned on, and as the high-level driving signal ds is transmitted to the intermediate node Nr, the voltage level of the intermediate node NR may increase to the high level identically to the driving signal ds and the first OR gate OR1 may output the high-level logic signal rs. In this case, the driving signal ds may be still at the high level, such that the second OR gate OR may output the high-level control signal cs.

As the low-level false signal fs temporarily occurs, the PMIC (130 of FIG. 1) may output the high-level false signal fs upon detecting that the state of the MCU 120 is recovered normally at t₂. The false signal fs may be returned to the high level. The transistor switch Q may be turned off, and the charge corresponding to the high voltage level of the driving signal ds stored in the capacitor C may start being discharged through the resistor R. The voltage level of the intermediate node Nr may exponentially decrease according to the time constant. However, as the voltage level of the intermediate node Nr is higher than the reference voltage level (e.g., 0.5 V), the first OR gate OR1 may output the high-level logic signal rs.

In this case, as the driving signal ds is still at the high level and the logic level of the logic signal rs is also high, the second OR gate OR2 may output the high-level control signal cs.

At t₃, the MCU 120 may output the low-level driving signal ds. Although the logic level of the driving signal ds goes low, the logic level of the logic signal rs is high, such that the second OR gate OR2 may output the high-level control signal cs.

The voltage level of the intermediate node Nr may slowly decrease, and may be lower than a reference voltage (e.g., 0.5 V) at t₄ when a preset retention time Td has elapsed from t₂. That is, the first OR gate OR1 may output the high-level logic signal rs up to t₄, and may output the low-level logic signal rs after t₄. The second OR gate OR2 may output the low-level control signal cs after ta at which the logic signal rs goes to the low level. At t₄, the first contactor 150 and the second contactor 160 may be opened by the low-level control signal cs and the battery 110 may be separated from the first pack terminal T1 and the second pack terminal T2.

In the gate control circuit 140a according to embodiments of the present disclosure, if the low-level false signal fs occurs due to a temporary communication failure, etc., the first contactor 150 and the second contactor 160 may maintain its immediately previous state for the preset retention time Td due to the retention function of the gate control circuit 140a.

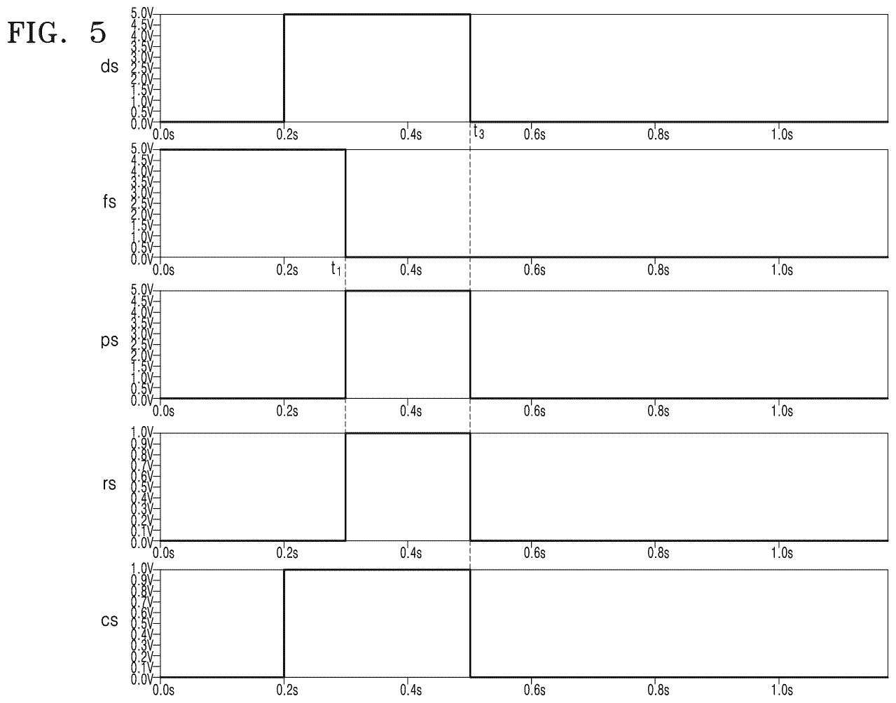

FIG. 5 is a signal waveform diagram of the contactor control circuit of FIG. 3.

Referring to FIG. 5, for example, a real failure occurs in the MCU 120.

At 0.0 s, the driving signal ds is at the low level and the false signal fs is at the high level. The transistor switch Q is turned off and the charge stored in the capacitor C is discharged through the resistor R, such that the intermediate node NR may output the low-level voltage signal ps. The first OR gate OR1 may also output the low-level logic signal rs, and the second OR gate OR2 may output the low-level control signal cs according to the low-level driving signal ds and the low-level logic signal rs.

At 0.2 s, the driving signal ds may transition to the high level. The second OR gate OR2 may output the high-level control signal cs according to the high-level driving signal ds. The first contactor 150 and the second contactor 160 may be short-circuited according to the high-level control signal cs. As the false signal fs is still at the high level, the transistor switch Q may maintain the turn-off state.

At t₁, the PMIC (130 of FIG. 1) may detect the false state of the MCU 120 and output the low-level false signal fs. If the false signal fs transitions to the low level, the transistor switch Q may be turned on, and as the high-level driving signal ds is transmitted to the intermediate node Nr, the voltage level of the intermediate node NR may increase to the high level identically to the driving signal ds and the first OR gate OR1 may output the high-level logic signal rs. In this case, the driving signal ds may be still at the high level, such that the second OR gate OR may output the high-level control signal cs.

If the driving signal ds transitions to the low level at t₃ when the false signal fs is at the low level, the low-level driving signal ds may be transmitted to the intermediate node Nr through the turned-on transistor switch Q. The voltage level of the intermediate node Nr may go to the low level identically to the driving signal ds, and the first OR gate OR1 may output the low-level logic signal rs. As the low-level driving signal ds and the low-level logic signal rs are input to the second OR gate OR, the low-level control signal cs may be output.

In the gate control circuit 140a according to embodiments of the present disclosure, if a real failure occurs in the MCU 120, the gate control circuit 140a may directly control the first contactor 150 and the second contactor 160 according to the driving signal ds without performing the retention function, thereby quickly dealing with the real failure of the MCU 120.

Certain embodiments shown and described herein are examples, and are not intended to limit the scope of embodiments in any way. For brevity, the description of conventional electronic configurations, control systems, software, and other functional aspects of the systems may be omitted. Connections of lines or connection members between components shown in the drawings are illustrative of functional connections and/or physical or circuit connections, and in practice, may be expressed as alternative or additional various functional connections, physical connections, or circuit connections. Unless there is no specific statement such as “essential”, “important”, etc., it is not considered an essential component.

In describing embodiments, the use of the term “the” and similar indicators thereof may correspond to both the singular and the plural. In addition, if the range is described in the embodiments, the range includes the disclosure to which an individual value falling within the range is applied (unless stated otherwise), and is the same as the description of an individual value constituting the range. Finally, if there is no apparent description of the order of operations constituting the method according to the present disclosure or a contrary description thereof, the operations may be performed in any appropriate order. However, the present disclosure is not necessarily limited according to the described order of the operations. The use of all examples or exemplary terms in the present disclosure are to simply describe the present disclosure in detail, and the range of the embodiments is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

Exemplary embodiments have been presented herein, and even if certain terms are used, these terms are not used for limited purposes, but should be interpreted as general and for explanation. In some examples, it may be clear to those of ordinary skill in the art at the time of filing the present application, but characteristics and/or components described in relation to certain embodiments may be used alone unless they are specifically described differently, and may be used with features and/or components described in connection with other embodiments. Thus, the spirit of the present disclosure should not be determined by being limited to the above-described embodiments, and not only the claims set forth below, but also any range equivalent to or equivalently changed from the claims falls within the scope of the spirit of the present disclosure.

According to the present disclosure, by simply implementing the contactor control circuit having the retention function with the switch transistor, the resistor-capacitor (RC) circuit, and the OR circuit, a manufacturing cost may be lowered. Moreover, the contactor may be maintained in the previous state for a predetermined time in response to a temporary false signal, whereas upon receipt of a real false signal, the contactor may be immediately controlled according to the driving signal. The battery pack may be provided which safely operates as the contactor control circuit according to the present disclosure performing different operations according to the temporary false signal and the real false signal.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims.

What is claimed is:

1. A contactor control circuit comprising:
a first input terminal receiving a driving signal;
a second input terminal receiving a false signal;
a resistor and a capacitor connected in parallel to each other between an intermediate node and a ground;
a transistor switch configured to transmit the driving signal to the intermediate node when the false signal is at a low level;
a logic OR circuit configured to generate a control signal by performing an OR operation on logic levels of the driving signal and the intermediate node; and
an output terminal outputting the control signal.

2. The contactor control circuit as claimed in claim 1, wherein the transistor switch comprises a pnp transistor comprising a base connected to the second input terminal, an emitter connected to the first input terminal, and a collector connected to the intermediate node.

3. The contactor control circuit as claimed in claim 1, wherein the OR circuit comprises:
a first OR gate configured to generate a logic signal by performing the OR operation on a voltage level of the intermediate node and a voltage of the ground; and
a second OR gate configured to generate the control signal by performing the OR operation on the driving signal and the logic signal.

4. The contactor control circuit as claimed in claim 1, wherein charge corresponding to a voltage level of the driving signal at a moment at which the transistor switch is turned off as the false signal transitions to a high level is charged in the capacitor.

5. The contactor control circuit as claimed in claim 4, wherein if charge corresponding to a first voltage level of the driving signal at a moment at which the transistor switch is turned off is charged in the capacitor, a voltage level of the intermediate node is maintained higher than a reference voltage level of the OR circuit for a preset retention time even if the charge charged in the capacitor is discharged through the resistor according to a time constant determined by a resistance of the resistor and a capacitance of the capacitor.

6. A battery pack comprising:
a first pack terminal and a second pack terminal;
a battery comprising at least one battery cell;
a contactor connected between the battery and the first pack terminal;
a micro control unit (MCU) configured to output a driving signal;
a power management integrated circuit (PMIC) configured to monitor a state of the MCU and output a false signal; and
a contactor control circuit configured to receive the driving signal through a first input terminal, receive the false signal through a second input terminal, generate, based on the driving signal and the false signal, a control signal for controlling the contactor, and output the control signal through an output terminal,
wherein the contactor control circuit comprises:
a resistor and a capacitor connected in parallel to each other between an intermediate node and a ground;
a transistor switch configured to transmit the driving signal to the intermediate node when the false signal is at a low level; and
a logic OR circuit configured to generate a control signal by performing an OR operation on logic levels of the driving signal and the intermediate node.

7. The battery pack as claimed in claim 6, wherein the MCU is further configured to output the driving signal of a first voltage level to short-circuit the contactor and output the driving signal of the low level to separate the contactor, and
the PMIC is further configured to output the false signal of the first voltage level when the MCU is in a normal state, and output the false signal of the low level when the MCU is monitored as being in a false state.

8. The battery pack as claimed in claim 6, wherein the transistor switch comprises a pnp transistor comprising a base connected to the second input terminal, an emitter connected to the first input terminal, and a collector connected to the intermediate node.

9. The battery pack as claimed in claim 6, wherein the OR circuit comprises:
a first OR gate configured to generate a logic signal by performing the OR operation on a voltage level of the intermediate node and a voltage of the ground; and
a second OR gate configured to generate the control signal by performing the OR operation on the driving signal and the logic signal.

10. The battery pack as claimed in claim 6, wherein charge corresponding to a voltage level at a moment at which the transistor switch is turned off as the false signal transitions to a high level is charged in the capacitor.

11. The battery pack as claimed in claim 10, wherein if charge corresponding to a first voltage level of the driving signal at a moment at which the transistor switch is turned off is charged in the capacitor, a voltage level of the intermediate node is maintained higher than a reference voltage level of the OR circuit for a preset retention time even if the charge charged in the capacitor is discharged through the resistor according to a time constant determined by a resistance of the resistor and a capacitance of the capacitor.
